(19) United States
(12) Patent Application Publication
(10) Pub. No.: US 2013/0331499 A1
(43) Pub. Date: Dec. 12, 2013

(54) SILICONE RESIN COMPOSITION AND AN OPTICAL SEMICONDUCTOR DEVICE PROVIDED WITH A CURED PRODUCT OBTAINED BY CURING THE SAME

(71) Applicant: SHIN-ETSU CHEMICAL CO., LTD., Tokyo (JP)

(72) Inventors: Yoshihira HAMAMOTO, Annaka-shi (JP); Tomoyuki MIZUNASHI, Annaka-shi (JP); Tsutomu KASHIWAGI, Annaka-shi (JP)

(21) Appl. No.: 13/907,006

(22) Filed: May 31, 2013

(30) Foreign Application Priority Data
Jun. 8, 2012 (JP) 2012-131156

(51) Int. Cl. H01L 33/56

(52) U.S. Cl. CPC H01L 33/56
USPC 524/500

(57) ABSTRACT

One object of the present invention is to provide a silicone resin composition which has remarkable discoloration resistance and durability of reflection efficiency, and provide an optical semiconductor device having high reliability. The present invention provides a silicone resin composition comprising (A) an organopolysiloxane resin represented by the formula (1) which has at least two alkenyl groups per molecule, (B) an linear organopolysiloxane represented by the formula (2), which has at least two alkenyl groups per molecule, provided that at least a part of a whole amount of components (A) and (B) has at least one cycloalkyl group per molecule, (C) an organohydrogenpolysiloxane represented by the formula (3) which has at least two SiH groups per molecule, in an effective amount to cure the components (A) and (B), and (D) an addition reaction catalyst in a catalytic amount.

### CROSS REFERENCE

This application claims the benefits of Japanese Patent Application No. 2012-131156 filed on Jun. 8, 2012, the contents of which are herein incorporated by reference.

### FIELD OF THE INVENTION

The present invention relates to a silicone resin composition which is used to encapsulate an optical semiconductor element and an optical semiconductor device provided with a cured product obtained by curing the same.

### BACKGROUND OF THE INVENTION

In recent years, high brightness LEDs which generate high intensity light and a large amount of heat have been commercialized and widely used for general purpose illuminations. Then, discoloration of an encapsulating material caused by a corrosive gas has been a problem. Japanese Patent Application Laid-Open No. 2005-272697 discloses that a hindered amine light degradation-preventive agent is added to a phenyl silicone resin to provide an encapsulating material having good heat resistance, good stable light resistance and good weather resistance. Japanese Patent Application Laid-Open No. 2009-215434 discloses that a silicone resin having an aliphatic hydrocarbon group as a substituent, such as a methyl silicone resin, prevents degradation of an organic resin package to extend a life of LED. Further, Japanese Patent Application Laid-Open No. 2000-17176 discloses that a silicone lens having cyclohexyl groups has low double refraction and is useful as optical materials.

However, the silicone resin described in Japanese Patent Application Laid-Open No. 2005-272697 has problems in the light resistance and heat discoloration resistance. The silicone resin described in Japanese Patent Application Laid-Open No. 2009-215434 has good impact resistance, but has high gas permeability and, therefore, has a problem in reliability in encapsulating materials against a corrosive gas. Further, it is known that the high gas permeability of the silicone resin leads to erosion of a silver-plated surface on a substrate which is used in an optical semiconductor device such as an LED to cause black discoloration, eventually, to decrease brightness of the LED. Therefore, there is a need to improve the silicone resin. The silicone resin composition described in Japanese Patent Application Laid-Open No. 2000-17176 has poor resistance to a high temperature and high moisture and poor light resistance. Therefore, when the silicone resin composition is used as an encapsulating material for an LED, the cured product is discolored to decrease the brightness of the LED. Therefore, the present inventors developed a silicone resin composition having remarkable low gas permeability, as described in the Japanese Patent Application Laid-Open No. 2012-7002.

### PRIOR LITERATURES

### Patent Literatures

[Patent Literature 1] Japanese Patent Application Laid-Open No. 2005-272697
[Patent Literature 2] Japanese Patent Application Laid-Open No. 2009-215434
[Patent Literature 3] Japanese Patent Application Laid-Open No. 2000-17176
[Patent Literature 4] Japanese Patent Application Laid-Open No. 2012-7002

### DISCLOSURE OF THE INVENTION

### Problems to be Solved by the Invention

A cycloalkyl group is sterically-bulky and, therefore, the silicone resin composition described in Japanese Patent Application Laid-Open No. 2012-7002 has remarkable low gas permeability. However, the silicone resin composition has still insufficient discoloration resistance and durability of reflection efficiency. Further, when an LED encapsulated with the composition is left under severe heat cycle or UV irradiation conditions, a silver-plated surface in an LED package is discolored to decrease the brightness of the LED.

One object of the present invention is to provide a silicone resin composition which has more remarkable discoloration resistance and durability of reflection efficiency and whose low gas permeability does not deteriorate under severe conditions, and provide an optical semiconductor device having higher reliability.

### Means to Solve the Problems

One of the causes of the discoloration by heat or light is that low gas permeability deteriorates due deterioration of a cycloalkyl group. When the cycloalkyl group deteriorates, the cured product loses the low gas permeability effect and, therefore, a silver-plated surface on an LED package erodes to cause black discoloration. To solve the aforesaid problems, the present inventors have made research and found that a composition which includes no SiO_{3/2} unit, namely, T unit, having a cycloalkyl group shows less deterioration of a cycloalkyl group. Then, an optical semiconductor element, such as a high luminosity LED, which is encapsulated with a cured product obtained by curing the silicone resin composition gives remarkable durability of discoloration and reflection efficiency.

Thus, the present invention provides a silicone resin composition comprising

(A) an organopolysiloxane resin represented by the following formula (1):

(R¹ₐR²_{b}R³_{c}SiO_{1/2})ₚ(R⁴_{d}R²ₑSiO_{2/2})_{q}(R³SiO_{3/2})ᵣ(SiO_{4/2})ₛ (1)

wherein R¹ is an alkenyl group having 2 to 8 carbon atoms, R² is a cycloalkyl group having 3 to 10 carbon atoms, R³ is a substituted or unsubstituted monovalent hydrocarbon group which has 1 to 10 carbon atom and is not a cycloalkyl group nor an alkenyl group, R⁴ is selected from the aforementioned groups defined for R¹ and R³; a, b and c are independently an integer of from 0 to 3, provided that a+b+c=3; d and e are independently an integer of from 0 to 2, provided that d+e=2; R¹, R², R³, R⁴, a, b, c, d and e may be the same with or different from each other among the parenthesized repeating units, provided that the organopolysiloxane resin has at least two alkenyl groups per molecule; p is the number of from 0.05 to 0.6, q is the number of from 0 to 0.4, r is the number of from 0 to 0.4, and s is the number of from 0.4 to 0.95, provided that p+q+r+s=1.0,

(B) an linear organopolysiloxane represented by the following formula (2) in an amount of 5 to 90 mass %, based on a total amount of components (A) and (B):

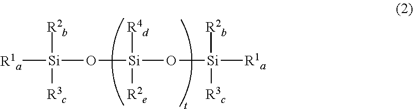

wherein t is an integer of from 1 to 2000, R¹, R², R³, R⁴, a, b, c, d and e are as defined above, provided that the linear organopolysiloxane has at least two alkenyl groups per molecule,

provided that at least a part of a whole amount of the components (A) and (B) has at least one R² per molecule,

(C) an organohydrogenpolysiloxane represented by the following formula (3) in an effective amount to cure components and (B):

(H_{a′}R²_{b′}R³_{c′}SiO_{1/2})_{f}(R⁵_{d′}R²_{e′}SiO_{2/2})_{g}(R³SiO_{3/2})ₕ(SiO_{4/2})ᵢ (3)

wherein R² and R³ are as defined above, R⁵ is a hydrogen atom or is selected from the aforementioned groups defined for R³; a′, b′ and c′ are independently an integer of from 0 to 3, provided that a′+b′+c′=3; d′ and e′ are independently an integer of from 0 to 2, provided that d′+e′=2; R², R³, R⁵, a′, b′, c′, d′ and e′ may be the same with or different from each other among the parenthesized repeating units, provided that the organopolysiloxane has at least two SiH groups per molecule; f is the number of from 0.01 to 0.7, g is the number of from 0.3 to 0.99, h is the number of from 0 to 0.5, and i is the number of from 0 to 0.4, provided that f+g+h+i=1.0, and

(D) an addition reaction catalyst in a catalytic amount. Further, the present invention provides an optical semiconductor device provided with a cured product obtained by curing the silicone resin composition,

### Effects of the Invention

The present silicone resin composition has remarkable durability of low gas permeability and reflection efficiency because of the less deterioration of a cycloalkyl group under severe heat cycle and UV irradiation conditions. Accordingly, the low gas permeability is maintained under the severe conditions, so that a highly reliable optical semiconductor device which has remarkable discoloration resistance and durable reflection efficiency is provided. Therefore, the present silicone resin composition is very suitable as an encapsulating material for LEDs requiring high heat resistance and light resistance.

### BEST MODE OF THE INVENTION

### (A) Organopolysiloxane Resin

The component (A) is an organopolysiloxane resin having at least two alkenyl groups per molecule, and is represented by the following formula (1). This organopolysiloxane resin has no unit represented by R′SiO_{3/2}, wherein R′ is a cycloalkyl group.

(R¹ₐR²_{b}R³_{c}SiO_{1/2})ₚ(R⁴_{d}R²ₑSiO_{2/2})_{q}(R³SiO_{3/2})ᵣ(SiO_{4/2})ₛ (1)

In the afore-mentioned formula (1), R¹ is an alkenyl group having 2 to 8 carbon atoms, R² is a cycloalkyl group having 3 to 10 carbon atoms, R³ is a substituted or unsubstituted monovalent hydrocarbon group which has 1 to 10 carbon atom and is not a cycloalkyl group nor an alkenyl group, R⁴ is selected from the aforementioned groups defined for R¹ and R³; a, b and c are independently an integer of from 0 to 3, provided that a+b+c=3; d and e are independently an integer of from 0 to 2, provided that d+e=2; and R¹, R², R³, R⁴, a, b, c, d and e may be the same with or different from each other among the parenthesized repeating units, provided that the organopolysiloxane resin has at least two alkenyl groups per molecule. p is the number of from 0.05 to 0.6, q is the number of from 0 to 0.4, r is the number of from 0 to 0.4, and s is the number of from 0.4 to 0.95, provided that p+q+r+s=1.0.

In the afore-mentioned formula (1), R¹ is an alkenyl group having 2 to 8, preferably 2 to 6, carbon atoms. Examples of R¹ include vinyl, allyl, propenyl, isopropenyl, butenyl, hexenyl, cyclohexenyl and octenyl groups. Among these, vinyl and allyl groups are preferred.

In the afore-mentioned formula (1), R² is a cycloalkyl group having 3 to 10, preferably 3 to 6, carbon atoms. Examples of R² include cyclopropyl, cyclobutyl, cyclopentyl, cyclohexyl, and cyclooctyl groups. Among these, cyclopentyl and cyclohexyl groups are preferred.

In the afore-mentioned formula (1), R³ is a substituted or unsubstituted monovalent hydrocarbon group which has 1 to 10, preferably 1 to 6, carbon atoms and is not a cycloalkyl group nor an alkenyl group. Examples of R³ include alkyl groups such as methyl, ethyl, propyl, isopropyl, butyl, isobutyl, tert-butyl, pentyl, neopentyl, hexyl, octyl, nonyl and decyl groups; aryl groups such as phenyl, tolyl, xylyl, and naphthyl groups; aralkyl groups such as benzyl, phenylethyl and phenylpropyl groups; and those groups where a part or the whole of their hydrogen atoms are replaced with a halogen atom(s), such as fluorine, bromine and chlorine atoms, or a cyano group, such as halogen-substituted alkyl groups, for instance, chloromethyl, chloropropyl, bromoethyl and trifluoropropyl groups, and a cyanoethyl group.

In the organopolysiloxane represented by the afore-mentioned formula (1), the molar ratio of R¹ₐR²_{b}R³_{c}SiO_{1/2} unit is “p”; the molar ratio of R⁴_{d}R²ₑSiO_{2/2} unit, “q”; the molar ratio of R³SiO_{3/2} unit, “r”; and the molar ratio of SiO_{4/2} unit, “s”. p is the number of from 0.05 to 0.6, q is the number of from 0 to 0.4, r is the number of from 0 to 0.4, and s is the number of from 0.4 to 0.95. Preferably, p is the number of from 0.1 to 0.6, q is the number of from 0 to 0.3, r is the number of from 0 to 0.1, and s is the number of from 0.5 to 0.9. Here, p+q+r+s=1.0. A weight average molecular weight of the organopolysiloxane resin, as determined by gel permeation chromatography (GPC) and reduced to polystyrene, is preferably in the range of 1,000 to 100,000, more preferably 2,000 to 50,000. In the present invention, the weight average molecular weight is determined in the following conditions throughout this specification.

Developing solvent: THF

Flow rate: 0.6 mL/min

Detector: Differential refractive index detector (RI)

Column: TSK Guardcolomn SuperH-L

TSKgel SuperH4000 (6.0 mmI.D.×15 cm×1)

TSKgel SuperH3000 (6.0 mmI.D.×15 cm×1)

TSKgel SuperH2000 (6.0 mmI.D.×15 cm×2)

(all produced by TOSO Co. Ltd.)

Column temperature: 40 degrees C.

Injection volume: 20 μL (0.5 weight % solution in THF)

In the organopolysiloxane represented by the afore-mentioned formula (1), a, b and c are independently an integer of from 0 to 3. Preferably, a is an integer of from 1 to 3, and b and c are independently an integer of from 0 to 2. Here, a+b+c=3. d and e are independently an integer of from 0 to 2. Preferably, d is an integer of from 0 to 1, and e is an integer of from 1 to 2. Here, d+e=2.

Examples of the organopolysiloxane resin represented by the afore-mentioned formula (1) include the following.

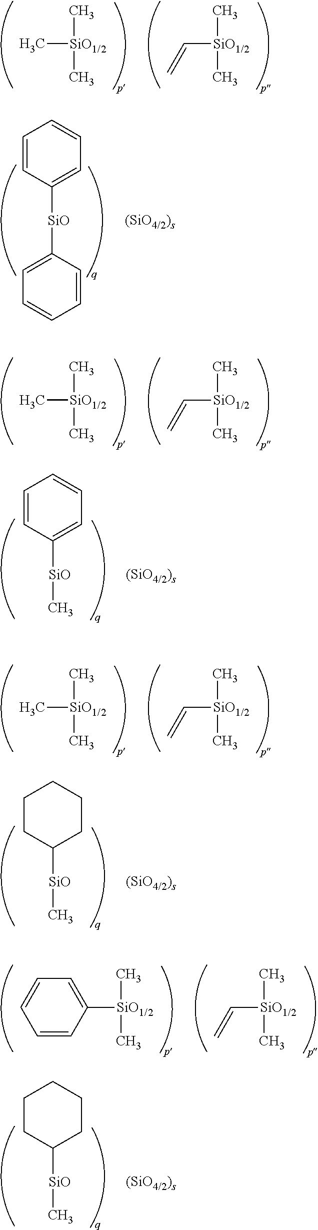

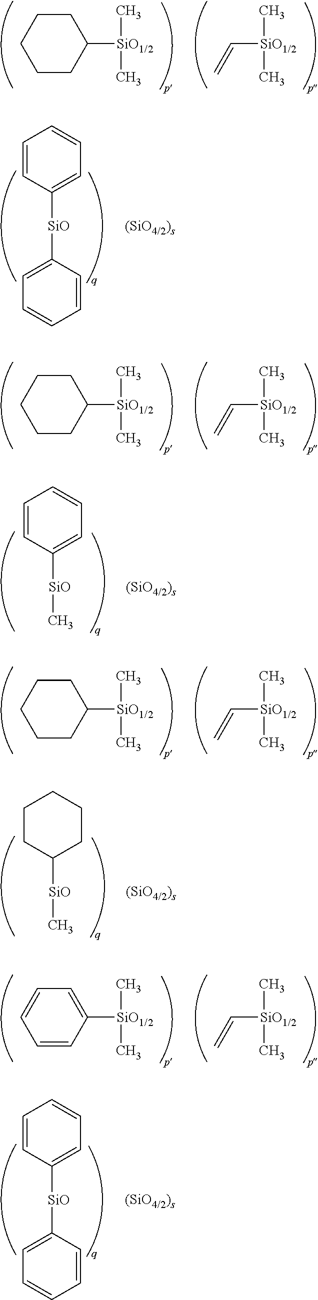

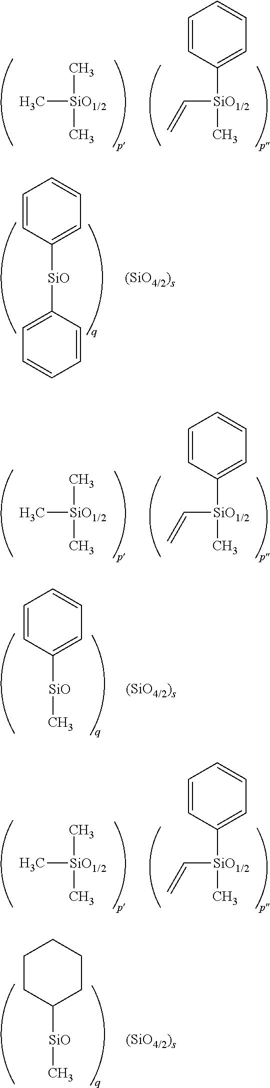

wherein p′ and p″ are the number which satisfy the equations, p′+p″=p, p′>=0 and p″>0. p, q and s are as defined above.

The organopolysiloxane having a resin structure is easily prepared by combining source compounds for each unit represented in the aforementioned parentheses so that the afore-mentioned molar ratios are met and, for instance, subjecting them to co-hydrolysis in the presence of an acid.

As the source compound for SiO_{4/2}, use may be made of tetramethoxysilane, tetraethoxysilane and tetrachlorosilane.

As the source compound for R⁴_{d}R²ₑSiO_{2/2}, use may be made of methoxysilanes such as dimethylmethoxysilane, diphenyldimethoxysilane, phenylmethyldimethoxysilane, cyclohexylmethyldimethoxysilane, dicyclohexyldimethoxysilane, cyclopentylmethyldimethoxysilane, and dicyclopentyldimethoxysilane; ethoxysilanes such as dimethyldiethoxysilane, phenylmethyldiethoxysilane, cyclohexylmethyldiethoxysilane, dicyclohexyldiethoxysilane, cyclopentylmethyldiethoxysilane, and dicyclopentyldiethoxysilane; and chlorosilanes such as dimethyldichlorosilane, diphenyldichlorosilane, phenylmeythyldichlorosilane, cyclohexylmethyldichlorosilane, dicyclohexyldichlorosilane, cyclopentylmethyldichlorosilane and dicyclopentyldichlorosilane.

As the source compound for R¹ₐR²_{b}R³_{c}SiO_{1/2} unit, the following compounds may be used:

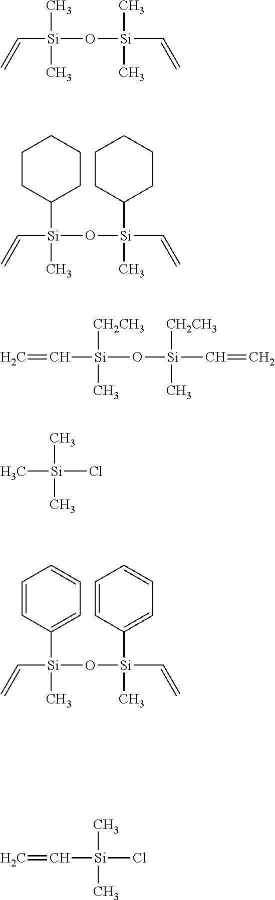

As the source compound for R³SiO_{3/2} unit, use may be made of methyltrimethoxysilane, phenyltriethoxysilane, methyltrichlorosilane and phenyltrichlorosilane.

The present organopolysiloxane resin may be a mixture of an organopolysiloxane resin having a cycloalkyl group and an organopolysiloxane resin having no cycloalkyl group, or may be an organopolysiloxane resin, alone, having no cycloalkyl group, provided that at least a part of a whole amount of components (A) and (B) has, per molecule, at least one cycloalkyl group bonding to a silicon atom.

The organopolysiloxane resin provides physical strength, low gas permeability and tackiness of a surface to a cured product. The amount of the organopolysiloxane resin is preferably 10 to 95 mass %, more preferably 20 to 80 mass %, further preferably 30 to 70 mass %, based on a total mass of the components (A) and (B). If the amount of the organopolysiloxane having a resin structure is too small, the aforesaid effects are not sufficiently attained. If the amount is too large, a viscosity of the composition is too high and cracks may occur in a cured product.

### (B) Linear Organopolysiloxane

The linear organopolysiloxane works to increase an elongation of the cured product and relax a stress of the cured product. Therefore, the linear organopolysiloxane can suppress cracks and peeling from a metal substrate in a heat shock test. In the present invention, the component (B) is a linear organopolysiloxane represented by the following formula (2).

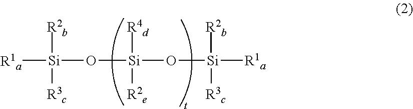

wherein t is an integer of from 1 to 2,000, preferably 1 to 1,000, and R¹, R², R³, R⁴, a, b, c, d and e are as defined above, provided that the linear organopolysiloxane has at least two alkenyl groups per molecule.

The linear organopolysiloxane preferably has a weight average molecular weight of 1,000 to 50,000, preferably 1,000 to 20,000, as determined by gel permeation chromatography (GPC) and reduced to polystyrene. The weight average molecular weight is determined in the afore-mentioned conditions. Additionally, the linear organopolysiloxane preferably has a viscosity at 25 degrees C. of 1,000 to 100,000 mPa·s, preferably 3,000 to 100,000 mPa·s, for good workability and curability. The viscosity is determined, for instance, with a rotational viscometer. The linear organopolysiloxane may have a small amount of RSiO_{3/2} units in the molecular chain, wherein R is not any cycloalkyl group.

Examples of the linear organopolysiloxane include the following.

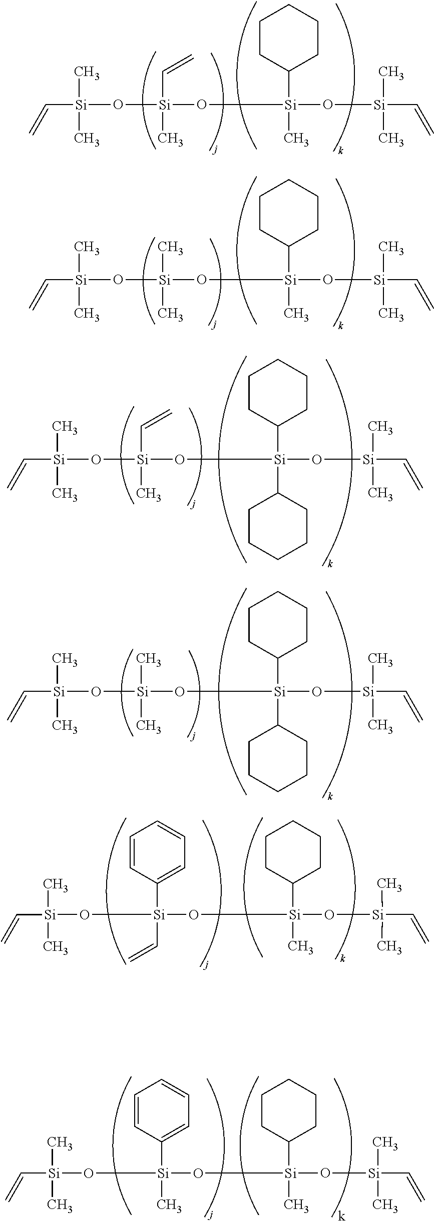

wherein j is an integer of from 1 to 100 and k is an integer of from 1 to 600.

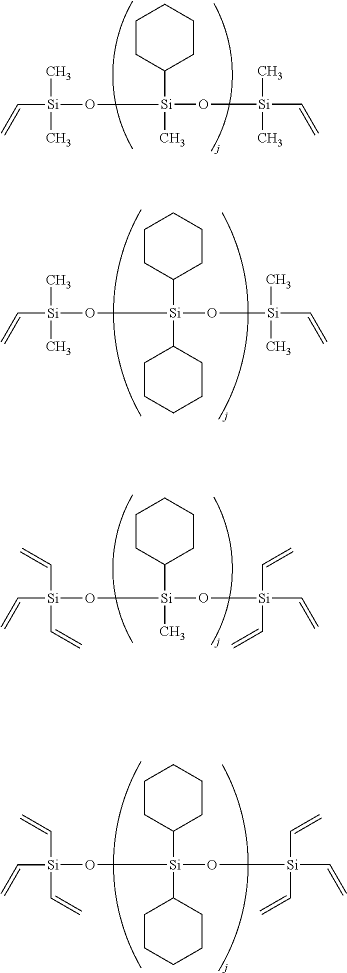

wherein j is an integer of from 1 to 600.

Examples of the linear organopolysiloxane which has no cycloalkyl group include the following.

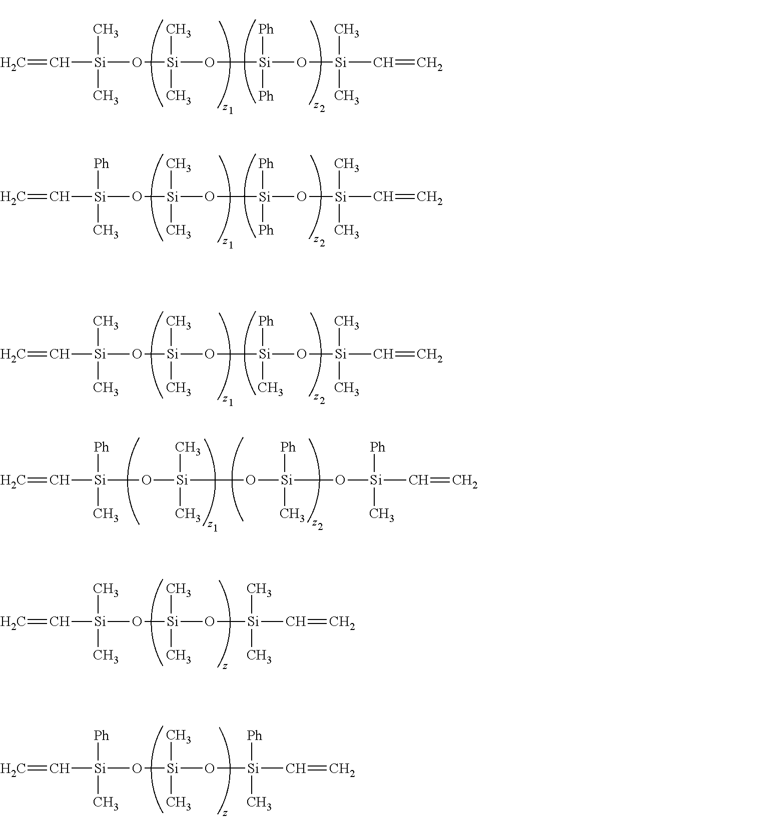

wherein z is an integer of from 1 to 1,000, preferably 5 to 500, more preferably 30 to 500. z₁ and z₂ are an integer which satisfy the equation 1<=z₁+z₂<=1,000, preferably 5<=z₁+z₂<=500, more preferably 30<=z₁+z₂<=500.

The present linear organopolysiloxane may be a mixture of an organopolysiloxane having a cycloalkyl group and an organopolysiloxane having no cycloalkyl group, or may be an organopolysiloxane, alone, having no cycloalkyl group, provided that at least a part of a whole amount of components (A) and (B) has, per molecule, at least one cycloalkyl group bonding to a silicon atom.

The amount of the linear organopolysiloaxane is preferably 5 to 90 mass %, preferably 20 to 80 mass %, more preferably 30 to 70 mass %, based on a total mass of the components (A) and (B). If the amount of the linear organopolysiloxane is too small, cracks may occur in a cured product. If the amount is too large, a surface of a cured product is so sticky that dust may adhere on the surface.

### (C) Organohydrogenpolysiloxane

Component (C) functions as a cross-linking agent (curing agent). The hydrogen atom bonded to a silicon atom in the component (C), hereinafter called “SiH group”, addition reacts with the alkenyl group in the components (A) and (B) to form a cross-linking structure. The organohydrogenpolysiloxane is represented by the following formula (3) and has no unit represented by R′SiO_{3/2}, wherein R′ is a cycloalkyl group.

(H_{a′}R²_{b′}R³_{c′}SiO_{1/2})_{f}(R⁵_{d′}R²_{e′}SiO_{2/2})_{g}(R³SiO_{3/2})ₕ(SiO_{4/2})ᵢ (3)

wherein R² and R³ are as defined above, R⁵ is a hydrogen atom or is selected from the aforementioned groups defined for R³; a′, b′ and c′ are independently an integer of from 0 to 3, provided that a′+b′+c′=3; d′ and e′ are independently an integer of from 0 to 2, provided that d′+e′=2; and R², R³, R⁵, a′, b′, c′, d′ and e′ may be the same with or different from each other among the parenthesized repeating units, provided that the organopolysiloxane has at least two SiH groups per molecule. f is the number of from 0.01 to 0.7, g is the number of from 0.3 to 0.99, h is the number of from 0 to 0.5, and i is the number of from 0 to 0.4, provided that f+g+h+i=1.0. Particularly, the organohydrogenpolysiloxane having at least two, preferably three or more, SiH groups per molecule is preferred.

In the organohydrogenpolysiloxane represented by the afore-mentioned formula (3), the molar ratio of H_{a′}R²_{b′}R³_{c′}SiO_{1/2} unit is “f”; the molar ratio of R⁵_{d′}R²_{e′}SiO_{2/2} unit, “g”; the molar ratio of R³SiO_{3/2} unit, “h”; and the molar ratio of SiO_{4/2} unit, “i”. f is the number of from 0.01 to 0.7, g is the number of from 0.3 to 0.99, h is the number of from 0 to 0.5, and i is the number of from 0 to 0.4. Preferably, f is the number of from 0.02 to 0.7, g is the number of from 0.4 to 0.98, h is the number of from 0 to 0.2, and i is the number of from 0 to 0.2. Here, f+g+h+i=1.0.

In the organohydrogenpolysiloxane represented by the afore-mentioned formula (3), a′, b′ and c′ are independently an integer of from 0 to 3. Preferably, a′ is an integer of from 1 to 3, b′ and c′ are independently an integer of from 0 to 2. Here, a′+b′+c′=3. d′ and e′ are independently an integer of from 0 to 2. Preferably, d′ is an integer of 0 or 1 and e′ is an integer of 1 or 2. Here, d′+e′=2.

The molecular structure of the organohydrogenpolysiloxane may be any of linear, cyclic, branched and three-dimensional network structures. The number of the silicon atoms in one molecule or the degree of polymerization is 3 to 1,000, preferably 3 to 100. A weight average molecular weight of the organohydrogenpolysiloxane, as determined by gel permeation chromatography (GPC), reduced to polystyrene, is in the range of 300 to 100,000, preferably 300 to 50,000. The weight average molecular weight is determined in the afore-mentioned conditions. Additionally, the organohydrogenpolysiloxane preferably has a viscosity at 25 degrees C. of 1 to 100,000 mPa·s, preferably 10 to 10,000 mPa·s for good workability and curability. The viscosity is determined, for instance, with a rotational viscometer. The SiH group may be present anywhere in the molecule, for instance, at the terminal or in a middle part of the molecular chain.

Examples of the organohydrogenpolysiloxane include tris(dimethylhydrogensiloxy)methylsilane, 1,1,3,3-tetramethyldisiloxane, 1,3,5,7-tetramethylcyclotetrasiloxane, methylhydrogenpolysiloxane with both ends blocked with trimethylsiloxy groups, copolymers of dimethylsiloxane and methylhydrogensiloxane with both ends blocked with trimethylsiloxy groups, dimethylpolysiloxane with both ends blocked with dimethylhydrogensiloxy groups, copolymers of dimethylsiloxane and methylhydrogensiloxane with both ends blocked with dimethylhydrogensiloxy groups, copolymers of methylhydrogensiloxane and diphenylsiloxane with both ends blocked with trimethylsiloxy groups, copolymers of methylhydrogensiloxane, diphenylsiloxane and dimethylsiloxane with both ends blocked with trimethylsiloxy groups, and copolymers composed of (CH₃)₂HSiO_{1/2} units and SiO_{4/2} units.

Organohydrogenpolysiloxane prepared from the units represented by the following structures can also be used.

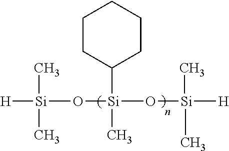

wherein n is an integer of from 1 to 10.

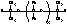

wherein n is an integer of from 1 to 10.

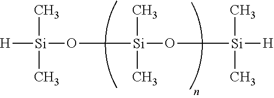

wherein n is an integer of from 3 to 200.

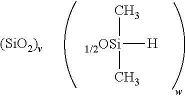

wherein v and w are the number which satisfy v>0, w>0 and the equation, v+w=1.0.

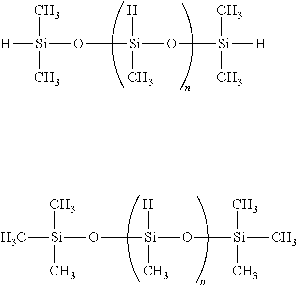

wherein n is an integer of from 1 to 100.

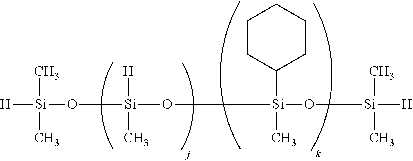

wherein j is an integer of from 1 to 100 and k is an integer of from 1 to 600.

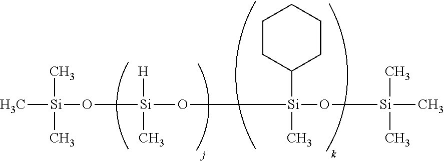

wherein j is an integer of from 1 to 100 and k is an integer of from 1 to 100.

This organohydrogenpolysiloxane can be prepared in any known methods, for instance, by hydrolyzing chlorosilane such as R⁶SiHCl₂, R⁶₃SiCl, R⁶₂SiCl₂ or R⁶₂SiHCl, wherein R⁶ is same as R² or R³ defined above, or by equilibrating the resulting siloxanes in the presence of a strong acid catalyst.

The amount of the organohydrogenpolysiloxane may be an effective amount to cure the components (A) and (B). The effective amount means such that the organohydrogenpolysiloxane addition-reacts with the components (A) and (B) to form a cross-linking structure so as to provide a cured product. In particular, the amount of the component (C) is such that a ratio of a total number of the SiH groups in the component (C) to a total number of the alkenyl groups in the components (A) and (B) is 0.5 to 4, preferably 0.9 to 2, more preferably 0.9 to 1.5. If the amount is smaller than the afore-mentioned lower limit, the curing reaction does not proceed enough to obtain a cured product. If the amount is larger than the afore-mentioned upper limit, a lot of unreacted SiH groups remain in a cured product to cause change in the rubber properties with time.

The amount of the cycloalkyl groups in the components (A), (B) and (C) is preferably 10 to 80 mass %, more preferably 20 to 80 mass %, further preferably 30 to 60 mass %, based on a total mass of the components (A), (B) and (C). If the content of the cycloalkyl groups is smaller than the aforementioned lower limit, gas permeability of a cured product is so high as to allow erosion of a silver surface in an LED package so as to decrease the brightness of the LED. If the content of the cycloalkyl group is larger than the aforementioned upper limit, the cured product obtained tends to cause discoloration and cracks by heat or light so as to decrease the brightness of the LED.

### (D) Addition Reaction Catalyst

The catalyst is added to accelerate an addition reaction. The catalyst may be a compound of the platinum group such as platinum, palladium or rhodium. Those comprising a metal of platinum are preferred in costs. Examples of the catalyst include H₂PtCl₆.mH₂O, K₂PtCl₆, KHPtCl₆.mH₂O, K₂PtCl₄, K₂PtCl₄.mH₂O, PtO₂.mH₂O, wherein m is a positive integer, RhCl(PPh₃)₃, RhCl(CO)(PPh₃)₂, Ru₃(CO)₁₂, IrCl(CO)(PPh₃)₂ and Pd(PPh₃)₄, wherein Ph represents a phenyl group. Complexes of the aforesaid catalysts of the platinum group with a hydrocarbon such as an olefin, an alcohol or a vinyl group-containing organopolysiloxane may be used. The afore-mentioned catalysts may be used alone or in combination thereof.

The catalyst may be used in a catalytic amount, preferably 0.0001 to 0.2 part by mass, more preferably 0.0001 to 0.05 part by mass, reduce to a platinum group metal, relative to total 100 parts by mass of the components (A), (B) and (C).

### (E) Adhesion-Imparting Agent

The present silicone resin composition may further comprise an adhesion-imparting agent in addition to components (A) to (D). Examples of the adhesion-imparting agent include vinyltrimethoxysilane, vinyltriethoxysilane, 2-(3,4-epoxycyclohexyl)ethyltrimethoxysilane, 3-glysidoxypropyltrimethoxysilane, 3-glysidoxypropylmethyldiethoxysilane, 3-glysidoxypropyltriethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, N-2(aminoethyl)-3-aminopropylmethyldimethoxysilane, N-2(aminoethyl)-3-aminopropyltrimethoxysilane, N-2(aminoethyl)-3-aminopropyltriethoxysilane, 3-aminopropyltrimethoxylsilane, 3-aminopropyltriethoxylsilane, N-phenyl-3-aminopropyltrimethoxylsilane and 3-mercaptopropyltrimethoxylsilane; and trimethoxysilane, tetramethoxysilane, and oligomers thereof. The afore-mentioned adhesion-imparting agent may be used alone or in combination thereof. The amount of the adhesion-imparting agent ranges from 0.1 to 10 mass %, preferably 0.5 to 5 mass %, relative to the total mass of the components (A), (B) and (C).

Organopolysiloxanes represented by the following formulas may also be used as the adhesion-imparting agent.

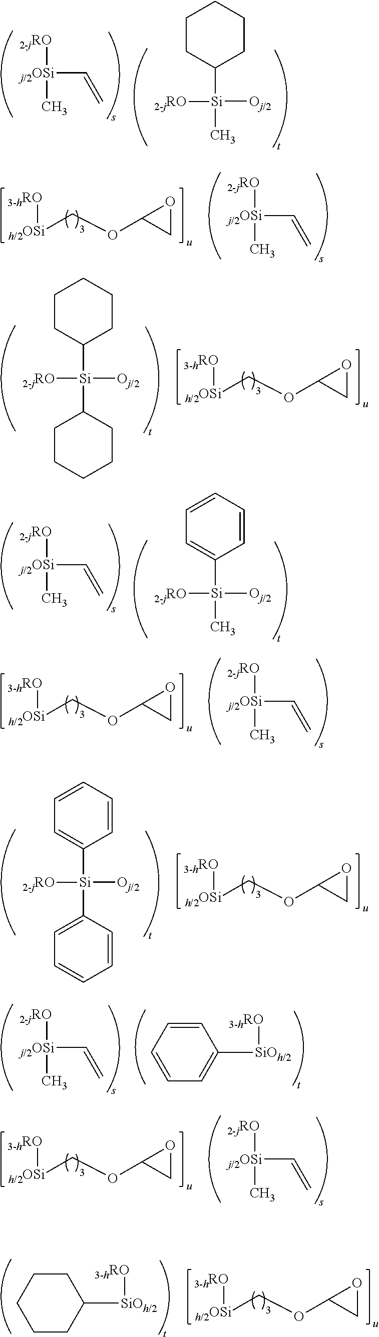

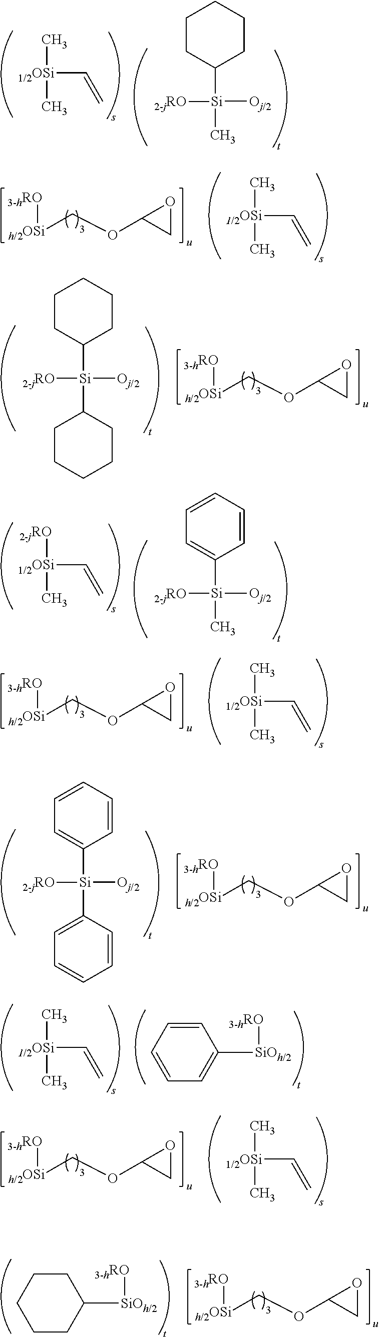

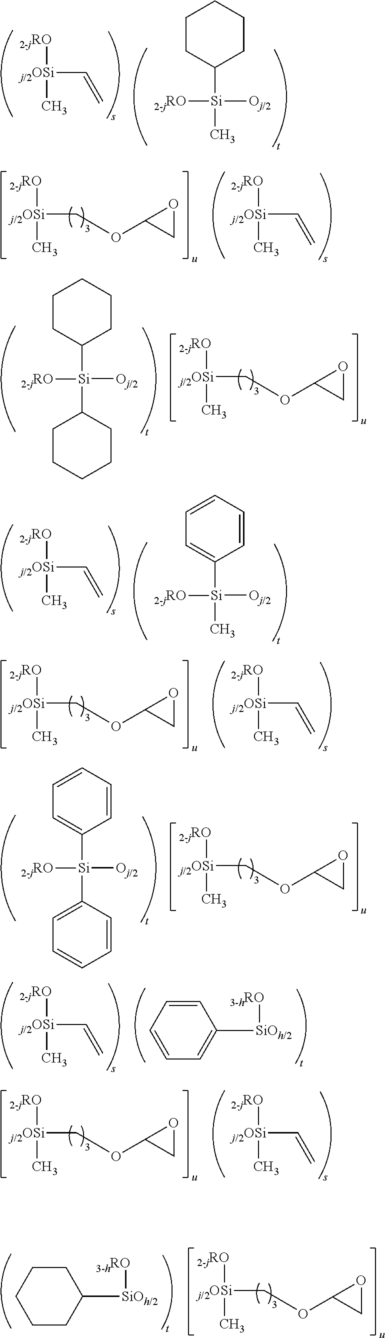

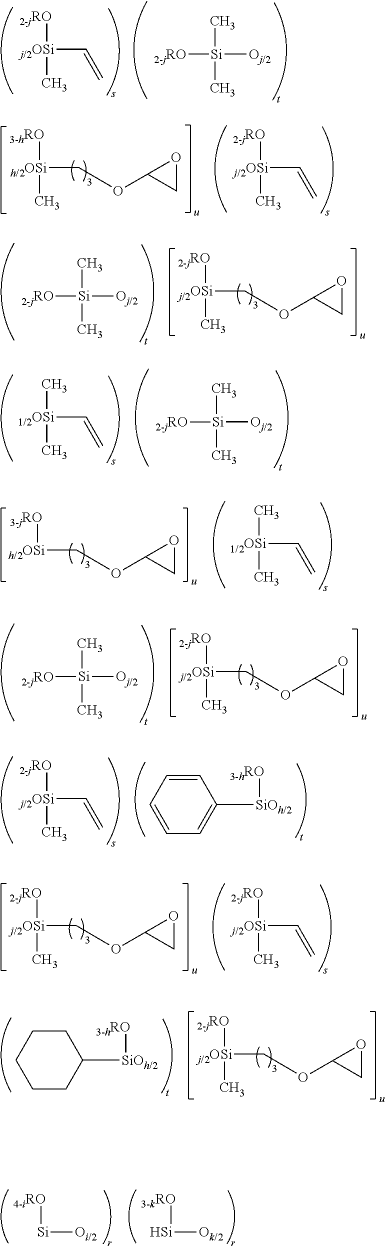

In the afore-mentioned formulas, R is a substituted or unsubstituted monovalent hydrocarbon group which has preferably 1 to 6 carbon atoms. Examples of R include alkyl groups such as methyl, ethyl, propyl, isopropyl, butyl, isobutyl, tert-butyl, pentyl, neopentyl, hexyl, octyl, nonyl and decyl groups. i is an integer of from 1 to 4, k is an integer of from 1 to 3, h is an integer of from 1 to 3, and j is an integer of 1 or 2. s, t and u are the number which satisfy the equations, 0<=s<=1, 0<=t<=1, and 0<=u<=1, provided that s+t+u=1. r is an integer which satisfy the equation, 1<=r<=100. Further, s, t, u, and r are such that the polymer has a weight average molecular weight of 1,000 to 20,000, preferably 1,000 to 10,000, more preferably 1,000 to 6,000, as determined by GPC, reduced to polystyrene.

In particular, preferred is the adhesion-imparting agent represented by the following formula.

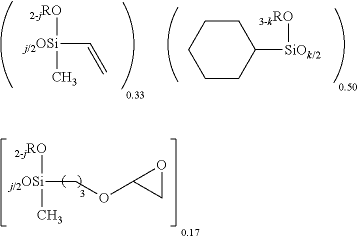

wherein j, k and R are as defined above.

When the adhesion-imparting agent has an alkenyl group, the amount of the component (C) is preferably such that a ratio of a total number of the SiH groups in the component (C) to a total number of the alkenyl groups in the components (A), (B) and (E) is 0.5 to 4.0, preferably 0.9 to 2.0, more preferably 0.9 to 1.5.

### (F) Antioxidant

The antioxidant may be added as a heat deterioration preventive agent to improve the heat resistance of the silicone resin composition. Any conventional antioxidant may be used. In particular, hindered phenol antioxidants are preferred. The amount of the antioxidant ranges from 0.001 to 3 parts by mass, preferably 0.05 to 1 part by mass, relative to the total 100 parts by mass of the components (A), (B) and (C). If the amount is the afore-mentioned lower limit or more, oxidation is prevented without losing the discoloration resistance of the cured product. If the amount is the afore-mentioned upper limit or less, the excessive antioxidant does not separate out on the surface of the cured product.

Examples of the antioxidant include pentaerythritol tetrakis[3-(3,5-di-tert-butyl-4-hydroxyphenyl)propionate], N,N′-propane-1,3-diylbis[3-(3,5-di-tert-butyl-4-hydroxyphenyl)propionamide], thiodiethylenebis[3-(3,5-di-tert-butyl-4-hydroxyphenyl)propionate], octadecyl-3-(3,5-di-tert-butyl-4-hydroxyphenyl)propionate, 6,6′-di-tert-butyl-2,2′-thiodi-p-cresol, N,N′-hexane-1,6-diylbis[3-(3,5-di-tert-butyl-4-hydroxyphenylpropionamide)], benzenepropanoic acid, 3,5-bis(1,1-dimethylethyl)-4-hydroxy, alkyl ester having C7-C9 side chain, diethyl[[3,5-bis(1,1-dimethylethyl)-4-hydroxyphenyl]methyl]phosphonate, 2,2′-ethylenebis[4,6-di-tert-butylphenol], 3,3′,3,5,5′,5″-hexa-tert-butyl-a,a′,a″-(mesitylene-2,4,6-triyl)tri-p-cresol, calciumdiethylbis[[[3,5-bis(1,1-dimethylethyl)-4-hydroxyphenyl]methyl]phosphonate], 4,6-bis(octylthiomethyl)-o-cresol, 4,6-bis(dodecylthiomethyl)-o-cresol, ethylenebis(oxyethylene)bis[3-(5-tert-butyl-4-hydroxy-m-tolyl)propionate], hexamethylenebis[3-(3,5-di-tert-butyl-4-hydroxyphenyl)propionate], 1,3,5-tris(3,5-di-tert-butyl-4-hydroxybenzyl)-1,3,5-triazine-2,4,6-trione, 1,3,5-tris[(4-tert-butyl-3-hydroxy-2,6-xylyl)methyl]-1,3,5-triazine-2,4,6-(1H, 3H, 5H)-trione, 6,6′-di-tert-butyl-4,4′-tiodi-m-cresol, diphenylamine, reaction product of N-phenylbenzenamine with 2,4,4′-trimethylpentene, 2,6-di-tert-butyl-4-(4,6-bis(octylthio)-1,3,5-triazin-2-ylamino)phenol, 3,4-dihydro-2,5,7,8-tetramethyl-2-(4,8,12-trimethyltridecyl)-2H-1-benzopyran-6-ol, 2′,3-bis[[3-[3,5-di-tert-butyl-4-hydroxyphenyl]propionyl]]propionohydrazide, didodecyl 3,3′-thiodipropionate and dioctadecyl 3,3′-thiodipropionate. Preferred are Irganox 245, 259, 295, 565, 1010, 1035, 1076, 1098, 1135, 1130, 1425WL, 1520L, 1726, 3114 and 5057, ex BASF Japan Ltd. These antioxidants may be used also in combination of two or more thereof.

The present silicone resin composition may further comprise conventional additives, if necessary, in addition to components (A) to (F). Examples of the additives include reinforcing inorganic fillers such as fumed silica and fumed titanium dioxide; non-reinforcing inorganic fillers such as calcium carbonate, calcium silicate, titanium dioxide, iron (III) oxide, carbon black and zinc oxide; light degradation-preventive agents such as hindered amine; and reactive diluents such as vinyl ethers, vinyl amides, epoxy resins, oxetanes, allyl phthalates and vinyl adipate. These additives may be properly added in such an amount that the purposes of the present invention are not obstructed.

### Method for Preparing the Silicone Resin Composition

The present silicone resin composition may be prepared by stirring, melting, mixing and dispersing the aforesaid components altogether or sequentially, if necessary, under heating. Typically, the components (A), (B) and (D), and the component (C) are stored in separate containers to avoid premature reaction, and mixed at the time of use to cause curing. If the component (C) and component (D) are stored together in one container, a dehydrogen reaction may occur. Therefore, it is preferred to store the component (C) and component (D) separately. Alternatively, a small amount of a cure inhibitor such as acetylene alcohol may be added to a mixture of the components (A), (B), (C) and (D) to store.

Any stirring apparatus can be used, such as a grinding machine equipped with a stirrer and a heater, a three-roll mill, a ball mill, and a planetary mixer. These apparatuses may be used in combination, if necessary. The viscosity of the present silicone resin composition, as determined at 25 degrees C. with a rotational viscometer, ranges preferably from 100 to 10,000,000 mPa·s, more preferably 300 to 500,000 mPa·s.

The present silicon resin composition provides a cured product whose moisture permeability at a thickness of 1 to 10 mm is 20 g/m²·day or less, preferably 15 g/m²·day or less, more preferably 10 g/m²·day or less. Smaller moisture permeability is more preferable. If the moisture permeability is larger than aforesaid upper limit, moisture passes through a cured product and a surface of metal on which the composition cured would erode in moisture-absorption degradation conditions. Further, the cured product swells to cause cracks, and peels at the interface. The afore-mentioned ranges of moisture permeability may be attained by that the silicone resin composition contains the cycloalkyl group of 10 to 80 mass %, preferably 20 to 80 mass %, more preferably 30 to 60 mass %, based on the total mass of the components (A), (B) and (C). The moisture permeability is determined according to the Japanese Industrial Standards (JIS) K 7129.

The silicone resin composition cures promptly, if necessary, by heating to provide a cured product which has good transparency and adheres very much to package materials such as LCP and to metal substrates. Therefore, the present silicone resin composition is suitable to encapsulate optical semiconductor elements. Examples of the optical semiconductor elements include LEDs, photodiodes, CCDs, CMOSes and photo couplers. In particular, the present silicone resin composition is suitable to encapsulate LEDs.

A method for encapsulating an optical semiconductor element using the present silicone resin composition may be chosen from any conventional methods, for specific optical semiconductor element. Curing conditions may usually be a temperature of 40 to 250 degrees C., preferably 60 to 200 degrees C., for 5 minutes to 10 hours, preferably 30 minutes to 6 hours, but are not limited to these.

When a silver plated lead frame is encapsulated with the cured product obtained from the present silicone resin composition, it is preferred that the surface of a silver plated lead frame is treated in advance to increase the wettability with the silicone resin composition. The surface treatment is preferably a dry method, such as ultraviolet treatment, ozone treatment and plasma treatment, for workability and maintenance of the equipment. The plasma treatment is particularly preferred. A material of a pre-molded package preferably contains a silicone component of 15 mass % or more, based on total mass of the organic components, to increase compatibility with the silicone resin composition. Here, the silicone component means a chemical compound having an SiO unit or a polymer thereof. If the amount of the silicone component is less than 15% by mass, the compatibility with the silicone resin composition is low, so that interstices (or voids) remain between the silicone resin composition and an inside wall of the pre-molded package in encapsulation operation, and an optical semiconductor device obtained tends to cause cracks.

### EXAMPLES

The present invention will be explained below in further detail with reference to a series of the Examples and the Comparative Examples, though the present invention is in no way limited by these Examples. In the following descriptions, Ph represents a phenyl group, Me represents a methyl group, Vi represents a vinyl group, and Cy represents a cyclohexyl group.

### Example 1

Mixed were 50 parts by mass of organopolysiloxane resin A1 as component (A), which consisted of 50 mole % of SiO_{4/2} units, 35 mole % of (CH₃)₃SiO_{1/2} units, and 15 mole % of PhMeViSiO_{1/2} units and had a vinyl group content of 6.12×10⁻¹ mol/100 g; 50 parts by mass of organopolysiloxane B1 represented by the following formula (4) as component (B);

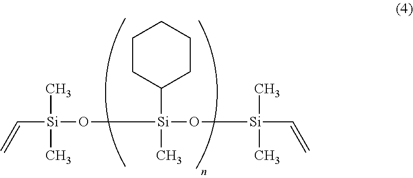

wherein average of n was 48,

organohydrogenpolysiloxane C1 represented by the following formula (5) as component (C), which had an SiH group content of 4.84×10⁻¹ mol/100 g, in an amount such that a ratio of a total number of the SiH groups in the component (C) to a total number of the vinyl groups in the components (A), (B) and (E), hereinafter referred to as SiH/Vi, was 1.1;

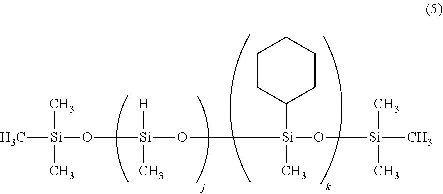

wherein average of j was 40 and average of k was 40,

and 0.05 part by mass of a solution of chloroplatinic acid in octyl alcohol, containing 2 mass % of platinum, as component (D), to which mixture was then added 2 parts by mass of adhesion-imparting agent 1 represented by the following formula (6) as component (E);

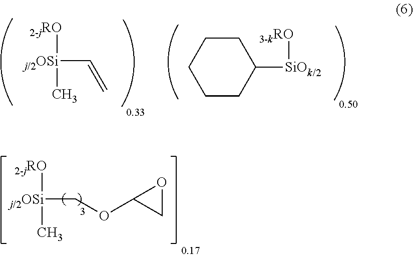

wherein R was a mixture of hydrogen atom, methyl and isopropyl groups, average of k was 2.97, average of j was 1.98, and the cyclohexyl group content was 34.1 mass %,

and 0.1 part by mass of Irganox 1076, ex BASF Japan Ltd., hindered phenol antioxidant, relative to the total 100 parts by mass of the components (A), (B) and (C), and sufficiently stirred to prepare a silicone resin composition. The amount of the cycloalkyl groups was 33.3 mass %, based on the total mass of the components (A), (B) and (C).

### Example 2

Mixed were 50 parts by mass of the aforesaid organopolysiloxane resin A1 as component (A), 50 parts by mass of the organopolysiloxane B1 represented by the aforesaid formula (4) as component (B), a mixture of the aforesaid organohydrogenpolysiloxane C1 and organohydrogensiloxane C2 represented by the following formula (7) which had an SiH group content of 4.31×10⁻¹ mol/100 g in amounts such that the number of the SiH groups of the organohydrogenpolysiloxane C1 was 25% and the number of the SiH groups of the organohydrogensiloxane C2 was 75%, based on the total number of the SiH groups in C1 and C2, as component (C), in an amount such that SiH/Vi was 1.1,

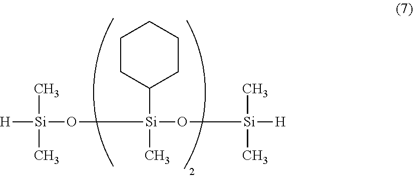

and 0.05 part by mass of a solution of chloroplatinic acid in octyl alcohol, containing 2 mass % of platinum, as component (D), to which mixture was then added 2 parts by mass of the adhesion-imparting agent 1 represented by the aforesaid formula (6) as component (E), and 0.1 part by mass of Irganox 1076, ex BASF Japan Ltd., hindered phenol antioxidant, relative to the total 100 parts by mass of the components (A), (B) and (C), and sufficiently stirred to prepare a silicone resin composition. The amount of the cycloalkyl groups was 38.6 mass %, based on the total mass of the components (A), (B) and (C).

### Example 3

Mixed were 50 parts by mass of organopolysiloxane resin A2 as component (A), which consisted of 46 mole % of SiO_{4/2} units, 14 mole % of CyMeSiO_{2/2} units, 28 mole % of Me₃SiO_{1/2} units and 12 mole % of PhMeViSiO_{1/2} units and had a vinyl group content of 4.82×10⁻² mol/100 g; 50 parts by mass of the organopolysiloxane B1 represented by the aforesaid formula (4) as component (B), the organohydrogenpolysiloxane C1 represented by the aforesaid formula (5) as component (C) in an amount such that SiH/Vi was 1.1, and 0.05 part by mass of a solution of chloroplatinic acid in octyl alcohol, containing 2 mass % of platinum, as component (D), to which mixture was then added 2 parts by mass of the adhesion-imparting agent 1 represented by the aforesaid formula (6) as a component (E), and 0.1 part by mass of Irganox 1076, ex BASF Japan Ltd., hindered phenol antioxidant, relative to the total 100 parts by mass of the components (A), (B) and (C), and sufficiently stirred to prepare a silicone resin composition. The amount of the cycloalkyl groups was 37.4 mass %, based on the total mass of the components (A), (B) and (C).

### Example 4

Mixed were 50 parts by mass of organopolysiloxane resin A3 as component (A), which consisted of 40 mole % of SiO_{4/3} units, 25 mole % of CyMeSiO_{2/2} units, 25 mole % of Me₃SiO_{1/2} units and 10 mole % of PhMeViSiO_{1/2} units and had a vinyl group content of 1.10×10⁻² mol/100 g; 50 parts by mass of the organopolysiloxane B1 represented by the aforesaid formula (4) as component (B), the organohydrogenpolysiloxane C1 represented by the aforesaid formula (5) as component (C) in an amount such that SiH/Vi was 1.1, and 0.05 part by mass of a solution of chloroplatinic acid in octyl alcohol, containing 2 mass % of platinum, as component (D) and sufficiently stirred to prepare a silicone resin composition. The amount of the cycloalkyl groups was 39.4 mass %, based on the total mass of the components (A), (B) and (C).

### Comparative Example 1

Mixed were 50 parts by mass of organopolysiloxane resin A4 as component (A), which consisted of 50 mole % of SiO_{4/2} units, 42.5 mole % of Me₃SiO_{1/2} units and 7.5 mole % of Me₂ViSiO_{1/2} units and had a vinyl group content of 1.72×10⁻² mol/100 g; 50 parts by mass of organopolysiloxane B2 represented by the following formula (8) as component (B),

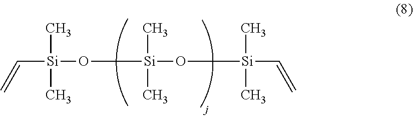

wherein average of j was 398,

organohydrogenpolysiloxane C3 represented by the following formula (9) as component (C) in an amount such that SiH/Vi was 1.1,

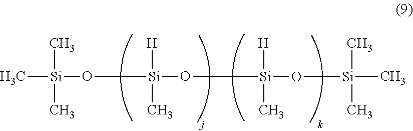

wherein average of j was 38 and average of k was 20, and 0.05 part by mass of a solution of chloroplatinic acid in octyl alcohol, containing 2 mass % of platinum, as a component (D), to which mixture was then added 2 parts by mass of adhesion-imparting agent 2 represented by the following formula (10) as component (E),

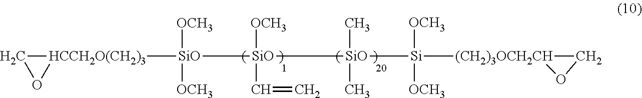

and sufficiently stirred to prepare a silicone resin composition.

### Comparative Example 2

The composition described in Japanese Patent Application Laid-Open No. 2012-7002 was prepared here.

Mixed were 79 parts by mass of organopolysiloxane resin A5 as component (A), which consisted of 70 mole % of CySiO_{3/2} units and 30 mole % of Me₂ViSiO_{1/2} units and had a vinyl group content of 2.03×10⁻¹ mol/100 g; 21 parts by mass of the organopolysiloxane B1 represented by the aforesaid formula (4) as component (B), and a mixture of 80 mass % of the organohydrogensiloxane C2 represented by the aforesaid formula (7) and 20 mass % of organohydrogensiloxane C4 represented by the following formula (11) which had an SiH group content of 8.10×10⁻¹ mol/100 g, as component (C), in an amount such that SiH/Vi was 1.1,

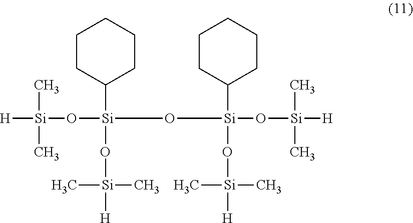 [SMILES: C[SiH](C)O[Si](O[SiH](C)C)(O[Si](O[SiH](C)C)(O[SiH](C)C)C1CCCCC1)C1CCCCC1]

and 0.03 part by mass of a solution of chloroplatinic acid in octyl alcohol, containing 2 mass % of platinum, as component (D), to which mixture was then added 2 parts by mass of the adhesion-imparting agent 1 represented by the aforesaid formula (6) as component (E), and 0.3 part by mass of Irganox 1076, ex BASF Japan Ltd., hindered phenol antioxidant, relative to the total 100 parts by mass of the components (A), (B) and (C), and sufficiently stirred to prepare a silicone resin composition. The amount of the cycloalkyl groups was 49.0 mass %, based on the total mass of the components (A), (B) and (C).

The silicone resin compositions prepared in Examples 1 to 4 and Comparative Examples 1 and 2 were each subjected to molding under heating at 150 degrees C. for 4 hours to obtain a cured product with a length of 110 mm, a width of 120 mm, and a thickness of 1 mm. Appearance of the cured products was observed by the naked eyes. Additionally, physical properties of the cured products were evaluated according to the following methods.

### Hardness (Shore A)

The hardness of the cured product was determined according to JIS K 6301. The results are as shown in Table 1.

### Tensile Strength

The tensile strength of the cured product was determined according to JIS K 6251. The results are as shown in Table 1.

### Elongation at Break

The elongation at break was determined according to JIS K 6251. The results are as shown in Table 1.

### Moisture Permeability

The moisture permeation rate, i.e., moisture permeability, of the cured product was determined in the Lyssy testing method with L80-5000, ex Lyssy company, according to JIS K 7129. The results are as shown in Table 1.

TABLE 1

| | | Ex. 1 | Ex. 2 | Ex. 3 | Ex. 4 | Com. Ex. 1 | Com. Ex. 2 |
|---|---|---|---|---|---|---|---|
| Appearance | | colorless | colorless | colorless | colorless | colorless | colorless |
| | | and | and | and | and | and | and |
| | | transparent | transparent | transparent | transparent | transparent | transparent |
| Hardness | Type A | 90 | 83 | 70 | 60 | 50 | 89 |
| Tensile strength | MPa | 1.8 | 2.8 | 2.5 | 1.5 | 3.2 | 0.8 |
| Elongation at break | % | 20 | 20 | 30 | 50 | 140 | 70 |
| Moisture permeation | g/m² * day | 12 | 7 | 5 | 5 | 58 | 2 |
| rate | | | | | | | |

Further, the optical semiconductor devices were encapsulated with cured products of the silicone resin compositions prepared in Examples 1 to 4 and Comparative Examples 1 and 2, as will be described below.

### Preparation of an LED Device

A cupped pre-molded package for an LED which had dimensions of 3 mm×3 mm×1 mm and an opening having a diameter of 2.6 mm and was equipped, on the bottom surface, with a copper lead frames plated with silver in a thickness of 2 μm were treated with argon plasma with 100 W power for 10 seconds of the exposure time. An electrode of an InGaN type blue light-emitting element was connected to the lead frame present at the bottom with a silver past, namely, conductive adhesive. A counter electrode of the light emitting element was connected to a counter lead frame with a gold wire. Then, each of the silicone resin compositions prepared in Examples 1 to 4 and Comparative Examples 1 and 2 was applied to the opening of each of the packages, and cured at 60 degrees C. for one hour and subsequently at 150 degrees C. for 4 hours to prepare LED devices.

While an electrical current of 25 mA was applied to the aforesaid LED devices to light on, the devices were left in a hydrogen sulfide gas atmosphere at 150 degrees C. for 1000 hours. Then, the extent of discoloration on the silver plated surface of the package was observed with the naked eyes. The results are as shown in Table 2.

### Heat Cycle Test

The LED devices prepared were subjected to a heat cycle test under the conditions described in Table 2, and observed with the naked eyes for bad adhesion at the interface of the package, cracks and discoloration. Besides, the total luminous flux, lm/w, namely, brightness, before and after the heat cycle test was measured with an LED total luminous flux and efficacy measuring instrument, C9929-22, ex Hamamatsu Photonics K.K. to determine a ratio of the values before and after the heat cycle. The percentage decrease was calculated based on the initial total luminous flux. The results are as shown in Table 2.

### UV Irradiation Test

The package was put in a UV irradiation instrument, UBX0601-03 Eye UV electronic control instrument, ex Eye Graphics Co., Ltd., and was left under the UV irradiation for a week, thus 168 hours and, then, observed with the naked eyes for bad adhesion at the interface of the package, cracks and discoloration. The results are as shown in Table 2.

TABLE 2

| | | Ex. 1 | Ex. 2 | Ex. 3 | Ex. 4 | Com. Ex. 1 | Com. Ex. 2 |
|---|---|---|---|---|---|---|---|
| Sulfuration test, | Appearance | Clear and | Clear and | Clear and | Clear and | Black | Clear and |
| 150° C./1000 hr | | colorless | colorless | colorless | colorless | discoloration | colorless |
| Heat cycle test, | Defection | 0/10 | 0/10 | 0/10 | 0/10 | 0/10 | 8/10 |
| −40 [symbol] 120° C./ | | | | | | | Cracks |
| 500 cycles | | | | | | | occurred |
| | Appearance | Clear and | Clear and | Clear and | Clear and | Clear and | Slightly |
| | | colorless | colorless | colorless | colorless | colorless | yellowing |
| Deterioration ratio | %, | 96 | 98 | 96 | 95 | 99 | 75 |
| of the brightness | relation to | | | | | | |
| | the initial | | | | | | |
| | value | | | | | | |
| UV irradiation test, | Defection | 0/10 | 0/10 | 0/10 | 0/10 | 0/10 | 5/10 |
| 168 hrs | | | | | | | Cracks |
| | | | | | | | occurred |
| | Appearance | Clear and | Clear and | Clear and | Clear and | Clear and | Yellowing |
| | | colorless | colorless | colorless | colorless | colorless | |

As shown in Tables 1 and 2, the cured product obtained from the composition of Comparative Example 1 including no cycloalkyl group had a high gas permeability. The cured product obtained by curing the composition of Comparative Example 2 which comprises an organosiloxane having T units having a cycloalkyl group, and is the composition described in Japanese Patent Application Laid-Open No. 2012-7002, had the remarkably low gas permeability, but showed the discoloration, decreased brightness and cracks under the severe heat cycle test and UV irradiation test. The cured products obtained from the present silicone resin compositions had the remarkably low gas permeabilities, and, moreover, showed no discoloration due to hydrogen sulfide on the silver plated surface of the package, no peeling, and no cracks under the severe heat cycle test and UV irradiation test and almost no decrease in brightness.

### INDUSTRIAL APPLICABILITY

The present silicone resin composition provides a cured product which has low gas permeability and remarkable heat resistance and durability of reflection efficiency, compared to conventional silicone compositions. Accordingly, the present silicone resin composition provides optical semiconductor devices having higher reliability, compared to conventional silicone compositions, and, therefore, is used as an encapsulating material for optical semiconductor devices.

1. A silicone resin composition comprising
(A) an organopolysiloxane resin represented by the following formula (1):
(R¹ₐR²_{b}R³_{c}SiO_{1/2})ₚ(R⁴_{d}R²ₑSiO_{2/2})_{q}(R³SiO_{3/2})ᵣ(SiO_{4/2})ₛ (1)
wherein R¹ is an alkenyl group having 2 to 8 carbon atoms, R² is a cycloalkyl group having 3 to 10 carbon atoms, R³ is a substituted or unsubstituted monovalent hydrocarbon group which has 1 to 10 carbon atom and is not a cycloalkyl group nor an alkenyl group, R⁴ is selected from the aforementioned groups defined for R¹ and R³; a, b and c are independently an integer of from 0 to 3, provided that a+b+c=3; d and e are independently an integer of from 0 to 2, provided that d+e=2; R¹, R², R³, R⁴, a, b, c, d and e may be the same with or different from each other among the parenthesized repeating units, provided that the organopolysiloxane resin has at least two alkenyl groups per molecule; p is the number of from 0.05 to 0.6, q is the number of from 0 to 0.4, r is the number of from 0 to 0.4, and s is the number of from 0.4 to 0.95, provided that p+q+r+s=1.0,
(B) an linear organopolysiloxane represented by the following formula (2) in an amount of 5 to 90 mass %, based on a total amount of components (A) and (B): 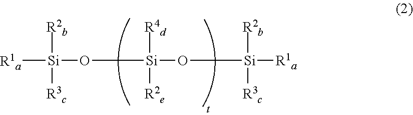
wherein t is an integer of from 1 to 2000, R¹, R², R³, R⁴, a, b, c, d and e are as defined above, provided that the linear organopolysiloxane has at least two alkenyl groups per molecule,
provided that at least a part of a whole amount of components (A) and (B) has at least one R² per molecule,
(C) an organohydrogenpolysiloxane represented by the following formula (3) in an effective amount to cure the components (A) and (B):
(H_{a′}R²_{b′}R³_{c′}SiO_{1/2})_{f}(R⁵_{d′}R²_{e′}SiO_{2/2})_{g}(R³SiO_{3/2})ₕ(SiO_{4/2})ᵢ (3)
wherein R² and R³ are as defined above, R⁵ is a hydrogen atom or is selected from the aforementioned groups defined for R³; a′, b′ and c′ are independently an integer of from 0 to 3, provided that a′+b′+c′=3; d′ and e′ are independently an integer of from 0 to 2, provided that d′+e′=2; R², R³, R⁵, a′, b′, c′, d′ and e′ may be the same with or different from each other among the parenthesized repeating units, provided that the organopolysiloxane has at least two SiH groups per molecule; f is the number of from 0.01 to 0.7, g is the number of from 0.3 to 0.99, h is the number of from 0 to 0.5, and i is the number of from 0 to 0.4, provided that f+g+h+i=1.0, and
(D) an addition reaction catalyst in a catalytic amount.

2. The silicone resin composition according to claim 1, wherein the amount of the component (C) is such that a ratio of a total number of the SiH groups in the component (C) to a total number of the alkenyl groups in the components (A) and (B) is 0.5 to 4.

3. The silicone resin composition according to claim 1, wherein the amount of the cycloalkyl group is 10 to 80 mass %, based on a total amount of the components (A), (B) and (C).

4. The silicone resin composition according to claim 1, wherein the composition further comprises an adhesion-imparting agent (E).

5. The silicone resin composition according to claim 1, wherein the composition further comprises an antioxidant (F).

6. The silicone resin composition according to claim 1, which provides a cured product showing a moisture permeability of 20 g/m²·day or less at a thickness of 1 to 10 mm.

7. An optical semiconductor device provided with a cured product obtained by curing the silicone resin composition according to claim 1.
